(19) United States
(12) Patent Application Publication
(10) Pub. No.: US 2026/0314151 A1
(43) Pub. Date: Oct. 8, 2026

(54) SEMICONDUCTOR DEVICE

(71) Applicant: ENNOSTAR CORPORATION, Hsinchu City (TW)

(72) Inventors: Jih-Kang CHEN, Hsinchu City (TW); Tzong-Liang TSAI, Hsinchu City (TW); Ching-Han LIAO, Hsinchu City (TW); Chia-Hao CHANG, Hsinchu City (TW); Hsien-Pen WU, Hsinchu City (TW); Chen OU, Hsinchu City (TW); Chi-Ling LEE, Hsinchu City (TW); Wen-Luh LIAO, Hsinchu City (TW); Cheng CHENG, Hsinchu City (TW); Yi-Syuan WU, Hsinchu City (TW); Chia-Hsin HUANG, Hsinchu City (TW)

(21) Appl. No.: 19/640,130

(22) Filed: Apr. 6, 2026

Related U.S. Application Data
(60) Provisional application No. 63/785,242, filed on Apr. 8, 2025.

(51) Int. Cl. H10H 29/85; H10H 20/819; H10H 29/14; H10H 29/80; H10W 10/17; H10W 10/20

(52) U.S. Cl. CPC H10H 29/857; H10H 20/819; H10H 29/14; H10H 29/8421; H10W 10/17; H10W 10/20

(57) ABSTRACT

A semiconductor device includes: a plurality of semiconductor units separated from each other by a trench; an insulating member disposed in the trench and over the plurality of semiconductor units; a connection electrode disposed on the insulating structure, extending laterally across the trench, and electrically connecting the plurality of semiconductor units; and a void disposed in the trench and defined by the insulating member; wherein the trench comprises a width W, and a vertical distance from a top surface of one of the plurality of semiconductor units to a bottom of the trench is L, with L/W being greater than or equal to 1.5.

### CROSS-REFERENCE TO RELATED APPLICATIONS

This application claims priority to and the benefit of U.S. provisional patent application No. 63/785,242 filed on Apr. 8, 2025, and the content of which is incorporated by reference in its entirety.

### BACKGROUND

### Technical Field

The present application provides a semiconductor device including a plurality of semiconductor units. present application relates to a semiconductor device, and in particular to a semiconductor device having a current blocking structure.

### Description of the Related Art

Semiconductor devices include compound semiconductors composed of Group III-V elements, such as gallium phosphide (GaP), gallium arsenide (GaAs), gallium nitride (GaN), and aluminum nitride (AlN). Semiconductor devices can be optoelectronic devices, for example, light-emitting diodes (LEDs), lasers, photodetectors, or solar cells. The semiconductor devices can also be power devices or acoustic wave devices. Among these, taking light-emitting diodes (LEDs) as an example of light-emitting components, solid-state LEDs feature low power consumption, low heat generation, long lifetime, small size, fast response, and excellent optoelectronic properties, such as stable emission wavelengths. Therefore, they have been widely used in household equipment, indicator lights, and optoelectronic products.

A conventional light-emitting diode (LED) includes a substrate; an n-type semiconductor layer, an active region, and a p-type semiconductor layer formed on the substrate; and a p-electrode and an n-electrode respectively formed on the p-type and n-type semiconductor layers. When the LED is forward biased to a certain value via the electrodes, holes from the p-type semiconductor layer and electrons from the n-type semiconductor layer are injected into the active region and recombine therein to emit light. As LEDs are applied to various optoelectronic products and their dimensions are reduced, maintaining their optoelectronic characteristics has become one of the objectives pursued by those skilled in the art.

### SUMMARY

A semiconductor device includes: a plurality of semiconductor units separated from each other by a trench; an insulating member disposed in the trench and over the plurality of semiconductor units; a connection electrode disposed on the insulating member and extending laterally across the trench, and electrically connecting the plurality of semiconductor units; and a void disposed in the trench and defined by the insulating member; wherein the trench comprises a width W, and a vertical distance from a top surface of one of the plurality of semiconductor units to a bottom of the trench is L, with L/W being greater than or equal to 1.5.

### BRIEF DESCRIPTION OF THE DRAWINGS

FIG. 1A is a plan view of a semiconductor device 1 according to an embodiment of the present application.

FIG. 1B is a cross-sectional view taken along line A-A′ of FIG. 1A.

FIG. 2 is a cross-sectional view of a semiconductor device 1 according to another variation of the present application.

FIG. 3 is a cross-sectional view of a semiconductor device 2 according to another embodiment of the present application.

FIG. 4 is a cross-sectional view of a semiconductor device 3 according to another embodiment of the present application.

FIG. 5 is a cross-sectional view of a semiconductor device 3 according to another variation of the present application.

FIG. 6 is a cross-sectional view of a semiconductor device 3 according to another variation of the present application.

FIG. 7A is a plan view of a semiconductor device 4 according to an embodiment of the present application.

FIG. 7B is a cross-sectional view taken along line A-A′ of FIG. 7A.

FIG. 7C is an enlarged partial view of FIG. 7B.

FIG. 7D is an enlarged partial view of FIG. 7B in accordance with another embodiment.

FIG. 8 shows a comparative example.

FIG. 9 is a cross-sectional view of a semiconductor device 5 according to another embodiment of the present application.

FIG. 10 is a cross-sectional view of a semiconductor device 6 according to another embodiment of the present application.

FIG. 11A is a plan view of a semiconductor device 7 according to another embodiment of the present application.

FIG. 11B is a cross-sectional view taken along line A-A′ of FIG. 11A.

FIG. 12 is a cross-sectional view of a semiconductor module according to an embodiment of the present application.

FIG. 13 is a schematic plan view of a display module according to an embodiment of the present application.

### DETAILED DESCRIPTION

To make the description of the present application more detailed and complete, reference is made to the following description of embodiments in conjunction with the accompanying drawings. However, the embodiments set forth below are provided by way of illustration of the semiconductor device of the present application. In some embodiments, the semiconductor device may be a semiconductor optoelectronic device such as a light-emitting diode (LED), a laser, a photodetector, or a solar cell. In other embodiments, the semiconductor device may be a power device. The semiconductor device primarily includes a buffer layer and a device structure formed on the buffer layer, with different device structures being formed depending on the device function. Taking a light-emitting device as an example, the structure may include a semiconductor light-emitting stack comprising a p-type semiconductor layer, an n-type semiconductor layer, and an active layer. The active layer includes an emission layer and can emit light in different wavelength bands depending on its material. The following provides multiple embodiments as descriptions relevant to the semiconductor device. It will be understood that the semiconductor devices in these embodiments are presented for illustrative purposes only and are not intended to limit the present application to the embodiments described below. In addition, unless otherwise specified, the dimensions, materials, shapes, relative arrangements, and the like of the constituent parts described in the embodiments are not limiting of the present application and are provided for explanatory purposes only. The sizes of and positional relationships among the components depicted in the drawings may be exaggerated for clarity of illustration. Throughout the description, identical or similar components are denoted by the same reference numerals, and repetitive explanations are omitted for brevity.

Unless otherwise specified in the present application, the AlGaN denotes AlₐGa₍₁₋ₐ₎N, where 0≤a≤1; the InGaN denotes In_{b}Ga_{(1-b)}N, where 0≤b≤1; and the AlInGaN denotes Al_{c}In_{d}Ga_{(1-c-d)}N, where 0≤c≤1 and 0≤d≤1. The AlInGaP denotes (AlₑIn₍₁₋ₑ₎)_{(1-f)}Ga_{f}P, where 0≤e≤1 and 0≤f≤1. The InGaAsP denotes In_{g}Ga_{(1-g)}AsₕP₍₁₋ₕ₎, where 0≤g≤1 and 0≤h≤1. By adjusting the contents of the constituent elements, different objectives can be achieved, including, without limitation, tuning the energy levels (e.g., bandgap) or the dominant emission wavelength of a light-emitting device.

The composition and dopants of each layer included in the semiconductor device in the present application may be analyzed by any suitable technique, such as secondary ion mass spectrometry (SIMS).

The width or thickness of each layer or structure included in the semiconductor device in the present application may be analyzed by any suitable technique, such as transmission electron microscopy (TEM) or scanning electron microscopy (SEM), for correlation with, for example, the depth positions of the respective layers on a SIMS profile.

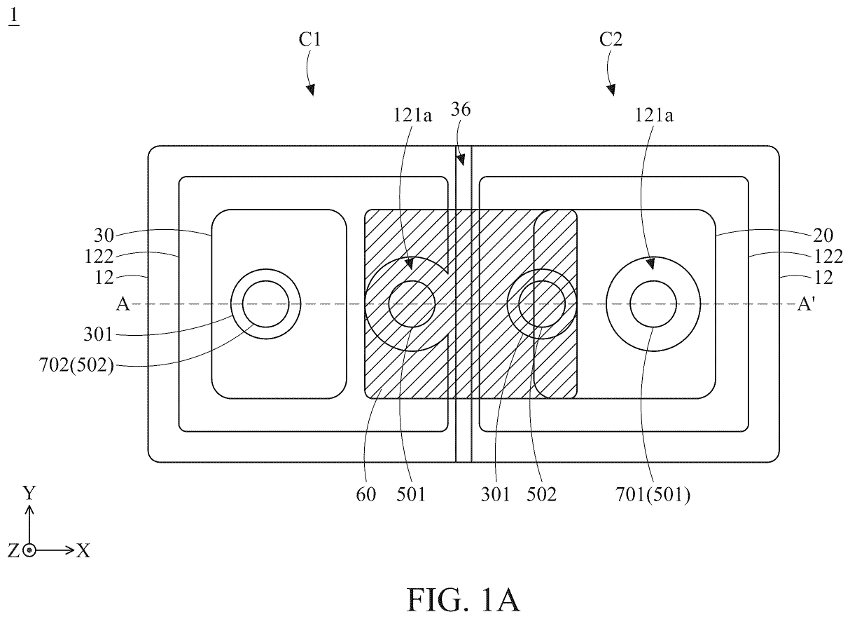

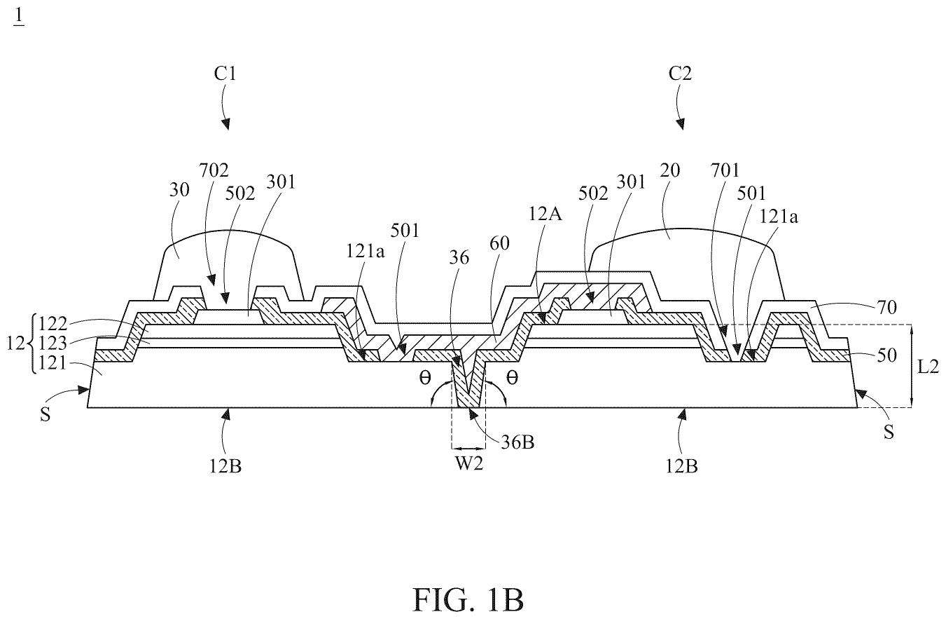

In detail, FIG. 1A shows a plan view of a semiconductor device 1 according to an embodiment of the present application. FIG. 1B is a cross-sectional view taken along line A-A′ of FIG. 1A.

As shown in FIGS. 1A and 1B, the semiconductor device 1 includes a plurality of semiconductor units, exemplified by C1 and C2, which are separated by a trench 36. The semiconductor units C1 and C2 are electrically connected via a connection electrode 60. In the present embodiment, the first semiconductor unit C1 and the second semiconductor unit C2 are provided as an example. However, the number of semiconductor units and the manner of electrical interconnection are not limited thereto. Each of the semiconductor units C1 and C2 includes a semiconductor stack 12. The semiconductor stack 12 includes a first semiconductor layer 121, an active region 123, and a second semiconductor layer 122. The first semiconductor layer 121 has an upper surface 121a that is not covered by the active region 123 and the second semiconductor layer 122. The sidewall of the trench 36 is defined by the opposing sidewalls of the semiconductor stacks 12 of the semiconductor units C1 and C2.

A current conduction layer 301 is disposed on, and is electrically connected to, the second semiconductor layer 122. In one embodiment, the semiconductor device 1 optionally includes a contact electrode (not shown) disposed between the current conduction layer 301 and the second semiconductor layer 122. The contact electrode forms good electrical contact with the second semiconductor layer 122, for example, an ohmic contact. A first insulating structure 50 covers the trench 36, the semiconductor stacks 12, and the current conduction layer 301, and has a first opening 501 that exposes the upper surface 121a of the first semiconductor layer 121 and a second opening 502 that exposes the current conduction layer 301. A connection electrode 60 overlies the first insulating structure 50. One end of the connection electrode 60 extends into the first opening 501 on the first semiconductor unit C1 to connect to the first semiconductor layer 121 of the first semiconductor unit C1, and the other end extends into the second opening 502 on the second semiconductor unit C2 to connect to the second semiconductor layer 122 of the second semiconductor unit C2. In this manner, the first semiconductor unit C1 and the second semiconductor unit C2 are electrically connected, for example, in series. The emission wavelengths of light emitted from the first semiconductor unit C1 and the second semiconductor unit C2 fall within the same color wavelength range. A second insulating structure 70 is optionally provided to cover the connection electrode 60, the first semiconductor unit C1 and the second semiconductor unit C2. The second insulating structure 70 has a first opening 701 overlapping the first opening 501, and a second opening 702 overlapping the second opening 502. A first electrode pad 20 is disposed on the second insulating structure 70 and extends into the first openings 501 and 701 to be electrically connected to the first semiconductor layer 121 of the second semiconductor unit C2. A second electrode pad 30 is disposed on the second insulating structure 70 and extends into the second openings 502 and 702 to be electrically connected to the second semiconductor layer 122 of the first semiconductor unit C1.

The semiconductor device 1 may be flip-chip bonded to a carrier (not shown). That is, the first electrode pad 20 and the second electrode pad 30 are respectively bonded to circuits on the carrier (not shown) via conductive bonding layers, so that light can be extracted from a bottom surface 12B of the semiconductor stack 12. The first electrode pad 20 and the second electrode pad 30 may be used as electrical terminals for the semiconductor stack 12 for receiving external power.

In some embodiments (not shown), the semiconductor device 1 may further include another current conduction layer disposed on the upper surface 121a of the first semiconductor layer 121 and electrically connected to the first semiconductor layer 121. In this case, the first opening 501 of the first insulating structure 50 may expose the current conduction layer on the upper surface 121a of the first semiconductor layer 121, and the first electrode pad 20 extends into the first opening 501 to connect to the current conduction layer on the upper surface 121a of the first semiconductor layer 121.

In some embodiments (not shown), one or both of the first insulating structure 50 and the second insulating structure 70 may further cover the sidewalls S of the semiconductor stack 12 at the periphery of the semiconductor device 1. In some embodiments (not shown), the first insulating structure 50 and/or the second insulating structure 70 may further cover the bottom surface 12B of the semiconductor stack 12.

A semiconductor device according to any embodiment described herein may have, in plan view, a diagonal length of 5-200 μm. In one embodiment, the semiconductor device 1 can be a microscale semiconductor device having a width and/or length in the range of 5-50 μm or in the range of 50-100 μm. In one embodiment, each of the semiconductor units C1 and C2 has, in plan view, a diagonal length of 5-20 μm.

As shown in FIG. 1B, the trench 36 includes a bottom 36B. In the present embodiment, the bottom 36B of the trench 36 may be defined by a virtual plane obtained by extending the bottom surfaces 12B of the semiconductor stacks 12 on both sides. The first insulating structure 50 fills the trench 36 and covers sidewalls of the trench 36. In one embodiment, the first insulating structure 50 may seal the trench bottom 36B. In other words, a bottommost surface of the first insulating structure 50 is substantially flush with the bottom surface 12B of the semiconductor stack 12, or a height difference between the bottommost surface of the first insulating structure 50 and the bottom surface 12B of the semiconductor stack 12 is less than 1 μm. In accordance with any embodiment of the present application, an included angle θ between the bottom surface 12B of the semiconductor stack 12 and a sidewall of the trench 36 is between 60° and 90°. In another embodiment, the included angle θ is between 75° and 90°. As shown in FIGS. 1A and 1B, the trench 36 has a length that is substantially equal to a short-side length of the semiconductor device 1 and has a maximum width W2. A vertical distance or height L2 is defined from the top surface 12A of the semiconductor stack 12 to the bottom 36B of the trench 36 (or to the bottom surface 12B). In one embodiment, L2/W2 is greater than or equal to 1.5. In one embodiment, 1.5≤L2/W2≤15. The maximum width W2 is less than 5 μm. In one embodiment, W2 is between 0.2 μm and 3 μm. The height L2 is between 2 μm and 5 μm. In one embodiment, a ratio of W2 to a diagonal length of the semiconductor unit is between 1% and 10%. With the size of the semiconductor device 1 held constant, reducing the maximum trench width W2 and setting the interior included angle θ within a specified range can increase, in plan view, the areas of the semiconductor units C1 and C2 and thus the total area of the active regions 123. Therefore, the brightness of the semiconductor device can be improved. In one embodiment, the maximum width W2 of the trench 36 is located at a top edge of the trench 36, and the maximum width W2 is greater than or equal to a width at the bottom 36B. The cross-sectional profile of the trench 36 may be a trapezoid that is wider at the top and narrower at the bottom.

In one embodiment, as shown in FIG. 1A, the connection electrode 60 may, in plan view, cover more than 50% of the length of the trench 36. In one embodiment, the connection electrode 60 has an area greater than that of either the first electrode pad 20 or the second electrode pad 30. In the absence of the semiconductor stack 12 within the trench 36, there may be a risk that the semiconductor device 1 fractures between the semiconductor units C1 and C2 in certain situations, such as during device transfer or die attach. By providing the connection electrode 60 that covers most of the trench 36, the semiconductor units C1 and C2 can be supported, thereby reducing the foregoing risk and improving the reliability of the semiconductor device 1.

In other variants of the semiconductor device 1 (not shown), the first insulating structure 50 may fill the trench 36 so that a substantially planar top surface is formed above the trench 36, instead of being conformal to sidewalls of the trench 36. In this way, the risk of fracture of the connection electrode 60 in the vicinity of the trench 36, for example due to variations in the topography of the first insulating structure 50, can be avoided.

### Semiconductor Stack 12

In one embodiment of the present application, the semiconductor stack 12 may be formed on a growth substrate (not shown) by a deposition process. The methods for forming the semiconductor stack 12 include metal-organic chemical vapor deposition (MOCVD), molecular beam epitaxy (MBE), hydride vapor phase epitaxy (HVPE), or ion plating, such as sputtering or evaporation. The growth substrate may be separated from, or removed from, the semiconductor stack 12 during fabrication of the semiconductor device 1 or after fabrication is completed.

In one embodiment, the semiconductor stack 12 may include a buffer structure (not shown) disposed on a side opposite to the electrode pads. For example, when the semiconductor stack 12 is formed on a substrate by MOCVD, the substrate may be selected as a growth substrate suitable for epitaxy, and the buffer structure can reduce lattice mismatch between the semiconductor stack 12 and the growth substrate during epitaxial growth and suppress dislocations, thereby improving epitaxial quality. The material of the buffer structure may include GaN, AlGaN, or AlN. In one embodiment, the buffer structure includes multiple sublayers (not shown), which may be made of the same material or different materials. In one embodiment, the buffer structure includes two sublayers, in which a formation method of a first sublayer differs from that of a second sublayer. For example, the first sublayer is formed by sputtering and the second sublayer is formed by MOCVD. In one embodiment, the buffer structure further includes a third sublayer, where the third sublayer is formed by MOCVD, and a growth temperature of the second sublayer is different from a growth temperature of the third sublayer. In one embodiment, the first, second, and third sublayers include the same material such as AlN. In one embodiment, the first semiconductor layer 121 and the second semiconductor layer 122 are cladding layers or confinement layers. In one embodiment, the first semiconductor layer 121 and the second semiconductor layer 122 have different conductivity types, electrical properties, polarities, or dopants used to supply electrons or holes. For example, the first semiconductor layer 121 includes an n-type semiconductor and the second semiconductor layer 122 includes a p-type semiconductor. Alternatively, the first semiconductor layer 121 includes a p-type semiconductor and the second semiconductor layer 122 includes an n-type semiconductor. The active region 123 is formed between the first semiconductor layer 121 and the second semiconductor layer 122. Under current injection, electrons and holes recombine in the active region 123 to convert electrical energy into optical energy to emit light. The wavelength of light emitted by the semiconductor device 1 or the semiconductor stack 12 can be adjusted by changing the physical properties and chemical composition of one or more layers in the semiconductor stack 12.

In some embodiments, the semiconductor stack 12 may be formed of III-V compound semiconductor materials, for example AlₓIn_{y}Ga_{(1-x-y)}N (AlInGaN) or AlₓIn_{y}Ga_{(1-x-y)}As_{z}P_{(1-z)}(AlInGaAsP), where 0≤x, y, z≤1 and x+y ≤1. Depending on the material of the active region, the semiconductor stack 12 can emit red light with a wavelength between 610 nm and 650 nm, yellow light between 550 nm and 570 nm, blue or deep-blue light between 400 nm and 490 nm, green light between 490 nm and 550 nm, ultraviolet light between 250 nm and 400 nm, or infrared light between 700 nm and 2500 nm. The active region 123 may be a single heterostructure (SH), a double heterostructure (DH), a double-side double heterostructure (DDH), or a multi-quantum well (MQW). The active region 123 may be formed of i-type, p-type, or n-type semiconductor. In other embodiments, the semiconductor stack 12 may include a dual-junction structure, for example including multiple active regions and a tunnel junction disposed between two adjacent active regions.

### Current Conduction Layer

The current conduction layer 301 includes metallic materials such as chromium (Cr), titanium (Ti), tungsten (W), gold (Au), aluminum (Al), rhodium (Rh), indium (In), tin (Sn), nickel (Ni), platinum (Pt), silver (Ag), beryllium (Be), or germanium (Ge), or a stack or an alloy of the foregoing materials. For example, the current conduction layer 301 may be a metal stack formed of an adhesion metal, an ohmic contact metal, a barrier metal, and a reflective metal. In one embodiment, the thickness of the current conduction layer 301 is between 0.3 μm and 3 μm. In different embodiments (not shown), the semiconductor device 1 may further include another current conduction layer disposed on the upper surface 121a of the first semiconductor layer 121. The current conduction layer that is electrically connected to the first semiconductor layer 121 and the current conduction layer 301 that is electrically connected to the second semiconductor layer 122 may have the same metal stack or different metal stacks.

In other embodiments (not shown), the semiconductor device 1 may omit the current conduction layer 301. The second opening 502 exposes the second semiconductor layer 122 or a contact electrode (not shown), and the second electrode pad 30 fills the openings 502 and 702 and is electrically connected to the second semiconductor layer 122.

### Connection Electrode

In some embodiments, the connection electrode 60 may include conductive materials, for example metallic materials such as chromium (Cr), titanium (Ti), tungsten (W), gold (Au), aluminum (Al), rhodium (Rh), indium (In), tin (Sn), nickel (Ni), platinum (Pt), silver (Ag), beryllium (Be), or germanium (Ge), or a stack or an alloy of the foregoing materials. For example, the connection electrode 60 may be a metal stack formed of an adhesion metal, a barrier metal, and a reflective metal. In one embodiment, the thickness of the connection electrode 60 may be greater than that of the current conduction layer 301.

### First Insulating Structure and Second Insulating Structure

The first insulating structure 50 and the second insulating structure 70 include insulating materials, which may be organic or inorganic. Examples of organic insulating materials include SU-8, benzocyclobutene (BCB), perfluorocyclobutane (PFCB), polyimide, epoxy, acrylic resin, cyclic olefin copolymer (COC), polymethyl methacrylate (PMMA), polyethylene terephthalate (PET), polycarbonate (PC), polyetherimide, and fluorocarbon polymers. Examples of inorganic insulating materials include silicone, glass, silicon oxide, silicon nitride, silicon oxynitride, niobium oxide, hafnium oxide, titanium oxide, magnesium fluoride, and aluminum oxide. The following description details the first insulating structure 50 and is equally applicable to the second insulating structure 70.

In some embodiments, the first insulating structure 50 may be a single insulating layer or a stack composed of multiple insulating layers. In one embodiment, the multiple insulating layers may include different materials. For example, the first insulating structure 50 may include a dense layer (not shown) and one or more insulating layers, wherein the dense layer is disposed at a bottommost portion of the first insulating structure 50 and directly covers the semiconductor stack 12. In one embodiment, the dense layer may be formed by atomic layer deposition (ALD) and have a thickness between 50 Å and 2000 Å, and more preferably between 100 Å and 1500 Å. The dense layer includes an insulating material, such as silicon oxide, aluminum oxide, hafnium oxide, zirconium oxide, yttrium oxide, lanthanum oxide, tantalum oxide, silicon nitride, aluminum nitride, or silicon oxynitride. In this embodiment, an interface between the dense layer and the semiconductor stack 12 comprises a metal element and oxygen, the metal element being selected from aluminum, hafnium, zirconium, yttrium, lanthanum, or tantalum. In one embodiment, the dense layer may conformally cover the underlying structure, for example over the semiconductor stack 12. Due to good step coverage of the dense layer, the dense layer can protect the underlying structure, for example, the dense layer can prevents moisture from entering the semiconductor stack 12.

In one embodiment, the first insulating structure 50 may include a stack formed by alternately stacking one or more pairs of a first sublayer and a second sublayer (not shown) having different refractive indices. By selecting materials with different refractive indices and designing their thicknesses, the first insulating structure 50 can reflect light within a specific wavelength range and/or a specific range of incidence angles, and thus can be used as a reflective structure. For example, the first insulating structure 50 may exhibit a reflectivity of at least 60% at the dominant wavelength and/or the peak wavelength of the light emitted from the semiconductor stack 12. In one embodiment, the first insulating structure 50 includes a distributed Bragg reflector (DBR). In one embodiment, the first insulating structure 50 has a thickness between 0.2 μm to 3 μm.

In other embodiments, the first insulating structure 50 may further include layers in addition to the first and second sublayers. For example, the first insulating structure 50 may further include an underlayer (not shown) disposed between the first/second sublayers and the semiconductor stack 12. That is, the underlayer is first formed on the semiconductor stack 12, followed by forming the first and second sublayers on the underlayer. The underlayer can provide protection for the semiconductor device or the semiconductor stack, for example, by blocking ingress of moisture into the semiconductor device. The underlayer includes insulating material, and its material may be the same as that of either the first or the second sublayer, or different from both. The thickness of the underlayer is greater than the thickness of each of the first and second sublayers. In one embodiment, the formation method of the underlayer is different from that of the first and second sublayers. For example, the underlayer is formed by chemical vapor deposition (CVD), and more preferably by plasma-enhanced chemical vapor deposition (PECVD), while the first and second sublayers are formed by sputtering or evaporation. In another embodiment, the underlayer is formed using the same method as the first and second sublayers. For example, the underlayer, the first sublayer, and the second sublayer are all formed by chemical vapor deposition or all formed by physical vapor deposition, such as evaporation, sputtering, or a combination thereof. In this way, the first insulating structure 50 can present a smooth surface.

In another embodiment, the first insulating structure 50 may further include an overlayer (not shown) disposed on the first and second sublayers, on a side opposite to the second semiconductor layer 122. That is, the first and second sublayers are first formed on the semiconductor stack 12, followed by formation of the overlayer. In one embodiment, the overlayer can increase the overall mechanical strength of the first insulating structure 50. For example, when the first insulating structure 50 is subjected to an external force, the overlayer can prevent the insulating structure 50 from cracking or being damaged. The overlayer includes insulating material, which may be the same as either the first sublayer or the second sublayer, or different from both. The thickness of the overlayer is greater than the thickness of each of the first and second sublayers. Similar to the aforementioned underlayer, the formation method of the overlayer may be different from, or the same as, that of the first and second sublayers. In another embodiment, the first insulating structure 50 includes the stack composed of the first and second sublayers, the underlayer and/or the overlayer. In different embodiments, the aforementioned dense layer may be disposed at the bottommost portion or the topmost portion of the first insulating structure 50, or between any two of the stack, the underlayer, and the overlayer.

### Electrode Pad

The electrode pads include the first electrode pad 20 and the second electrode pad 30, which include metallic materials such as chromium (Cr), titanium (Ti), tungsten (W), gold (Au), aluminum (Al), indium (In), tin (Sn), nickel (Ni), platinum (Pt), or silver (Ag), or a stack or an alloy of the foregoing materials. The first electrode pad 20 and the second electrode pad 30 may be used as current paths for delivering electrical power from an external power source to the first semiconductor layer 121 and the second semiconductor layer 122. In one embodiment, the first electrode pad 20 and the second electrode pad 30 have a multilayer structure. For example, the metal structure of the first electrode pad 20 and the second electrode pad 30 for connection to an external power source may be formed as a multilayer stack of Au and Sn layers, or of Sn and Ag layers. Sn, Au, or Ag may serve as the outermost metal of the first electrode pad 20 and the second electrode pad 30.

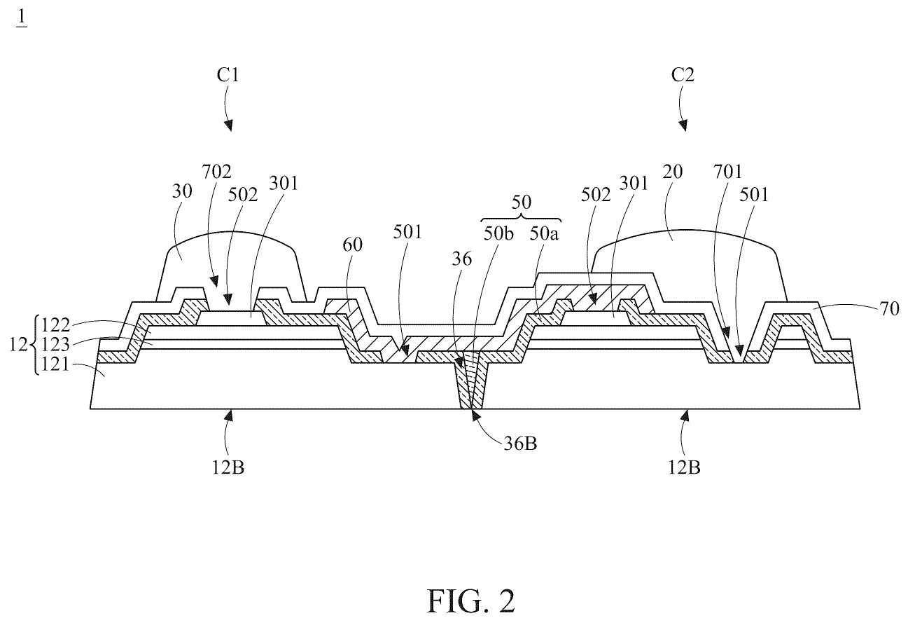

FIG. 2 shows a cross-sectional view of the semiconductor device 1 according to another variation of the present application. Compared with the semiconductor device 1 of FIG. 1, the difference is that the first insulating structure 50 in FIG. 2 includes a first insulating layer 50a that covers the semiconductor units C1 and C2 and the trench 36, and a second insulating layer 50b disposed on the first insulating layer 50a within the trench 36. In one embodiment, the second insulating layer 50b can fill the trench 36 such that the portion of the first insulating structure 50 above the trench 36 has a substantially planar top surface. In this way, the risk of fracture of the connection electrode 60 over the trench 36 can be reduced. In one embodiment, the first insulating layer 50a may be selected from the aforementioned inorganic insulating materials, and the second insulating layer 50b may be selected from the aforementioned organic insulating materials. However, the embodiments are not limited thereto. In other embodiments, the first insulating layer 50a may be a single layer or a multilayer structure.

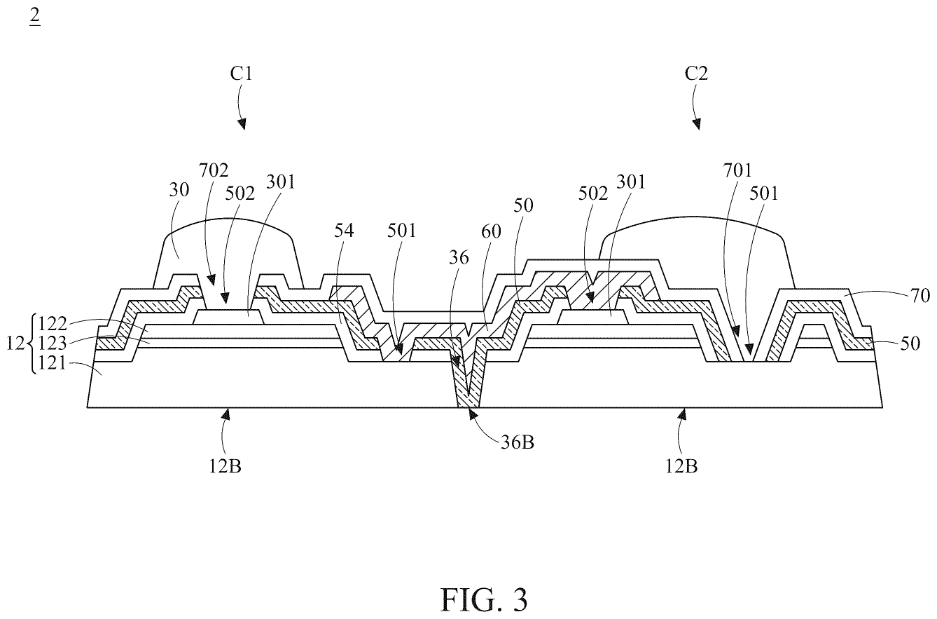

FIG. 3 shows a cross-sectional view of the semiconductor device 2 in accordance with another embodiment of the present application. The difference from the semiconductor device 1 is that the semiconductor device 2 includes an insulating reflective structure 54 disposed between the semiconductor stack 12 and the first insulating structure 50. In some embodiments, the insulating reflective structure 54 or/and the first insulating structure 50 may constitute an insulating member disposed in the trench 36 and over the plurality of semiconductor units C1 and C2. As shown in FIG. 3, the insulating reflective structure 54 is respectively formed over the first semiconductor unit C1 and the second semiconductor unit C2, does not cover the trench 36, and has openings at positions corresponding to the first opening 501 and the second opening 502 of the first insulating structure 50. The specific materials and configuration of the insulating reflective structure 54 may be the same as those described above for the first insulating structure 50. For example, it may include a distributed Bragg reflector (DBR) that enhances light extraction through the bottom surface 12B of the semiconductor stack 12. In this embodiment, because the semiconductor device 2 includes the insulating reflective structure 54, the first insulating structure 50 and the second insulating structure 70 may be selected as a multilayer structure or a single layer that does not include a reflective structure.

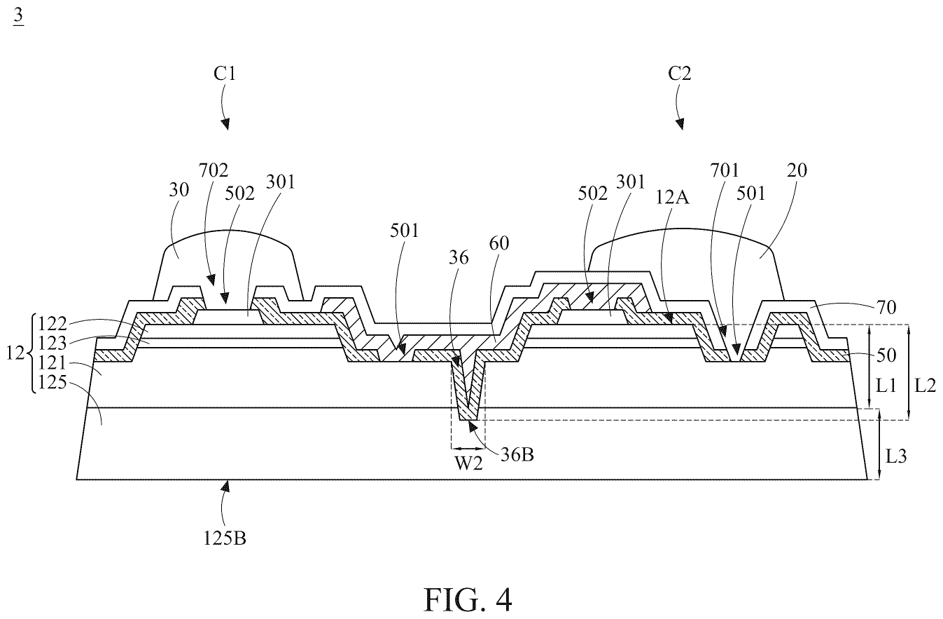

FIG. 4 shows a cross-sectional view of the semiconductor device 3 in accordance with another embodiment of the present application. The difference from the semiconductor device 1 is that the semiconductor stack 12 of the semiconductor device 3 includes a high-resistivity layer 125, with the first semiconductor unit C1 and the second semiconductor unit C2 disposed on the high-resistivity layer 125. The bottom surface 125B of the high-resistivity layer 125 may serve as the light extraction surface of the semiconductor device 3. The trench 36 may selectively extend into the high-resistivity layer 125 so that the bottom 36B of the trench 36 is defined by a portion of the surface of the high-resistivity layer 125. As shown in FIG. 4, the vertical distance from the top surface 12A of the semiconductor stack 12 to the bottom 36B is L2, the vertical distance from the top surface of the semiconductor stack 12 to the bottom of the first semiconductor layer 121 is L1, and the thickness of the high-resistivity layer 125 is L3. In one embodiment, L2 is greater than L1; that is, the depth of the trench 36 extends beyond the bottom of the first semiconductor layer 121. In one embodiment, L3 may be greater than or less than L2. In one embodiment, L2/W2 is greater than or equal to 1.5. The high-resistivity layer 125 can support the semiconductor units C1 and C2, increase the overall mechanical strength of the semiconductor device 3, and reduce the risk of fracture in the vicinity of the trench 36. By making L2 greater than L1, leakage current between the semiconductor units C1 and C2 can be prevented, thereby ensuring normal operation when the semiconductor units are electrically interconnected.

In some embodiments, the high-resistivity layer 125 has a sheet resistance greater than 1×10⁶ ohms per square (Ω/sq), and its material may be selected from the materials of the semiconductor stack 12 described above. In one embodiment, the high-resistivity layer 125 includes GaN and a dopant, wherein the dopant includes iron (Fe) or carbon (C), and L3 is less than L2. In another embodiment, the high-resistivity layer 125 includes undoped GaP or AlGaInP, and L3 is greater than L2. Alternatively, iron (Fe) or hydrogen (H) may be doped into GaP or AlGaInP. The dopant is not limited to the foregoing examples and may be selected according to the material of the semiconductor stack 12 to form the high-resistivity layer 125. The high-resistivity layer 125 may be formed by introducing the dopant during epitaxial growth, or by introducing the dopant into the semiconductor layer via ion implantation or thermal diffusion to achieve high resistivity. In one embodiment, the high-resistivity layer 125 and the first semiconductor layer 121 may include the same material. Using suitable analytical tools, such as secondary ion mass spectrometry (SIMS), the dopant in the high-resistivity layer 125 can be observed, thereby defining the position of the top surface of the high-resistivity layer 125.

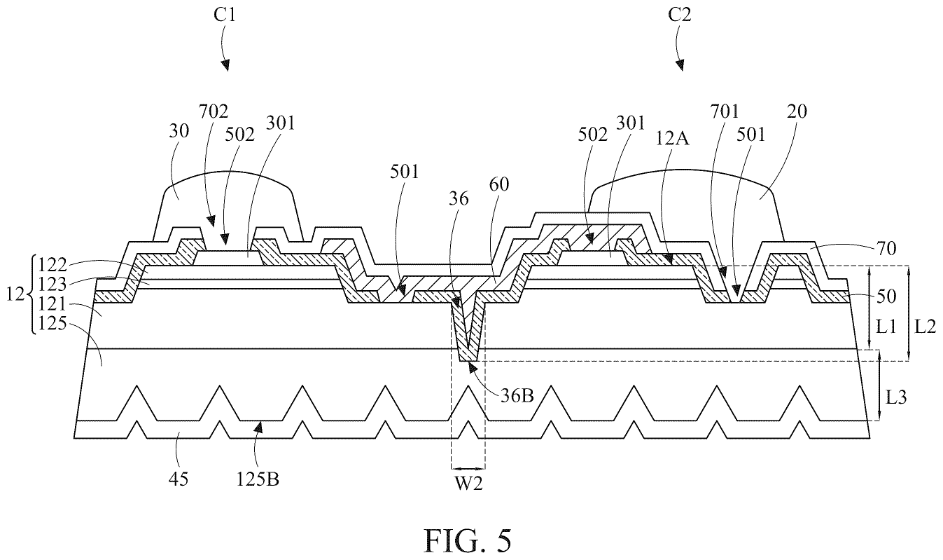

FIG. 5 shows a cross-sectional view of the semiconductor device 3 in accordance with another variation of the present application. The difference from FIG. 4 is that the bottom surface 125B of the high-resistivity layer 125 includes a light-extraction structure. In the present embodiment, the light-extraction structure includes a patterned structure, which may be a plurality of protrusions or a plurality of recesses, thereby enhancing light extraction.

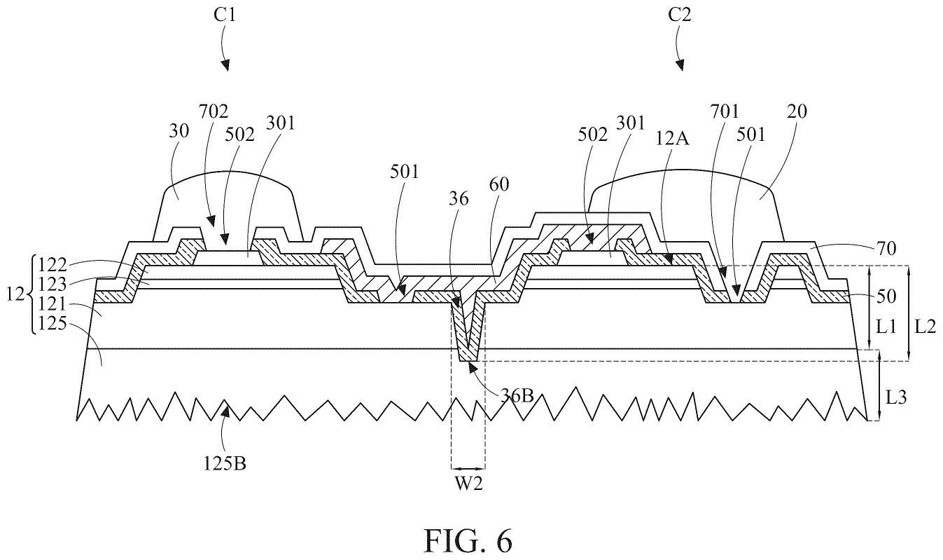

FIG. 6 shows a cross-sectional view of the semiconductor device 3 in accordance with another variation of the present application. The difference from FIG. 4 is that the light-extraction structure on the bottom surface 125B of the high-resistivity layer includes a roughened structure. The roughened structure can be irregularly distributed. Additionally, in the semiconductor device 3 shown in FIG. 5 or FIG. 6, an optional dielectric layer 45 may cover the bottom surface 125B. In one embodiment, the dielectric layer 45 has a refractive index between 1 (air) and that of the high-resistivity layer 125, thereby enhancing light extraction.

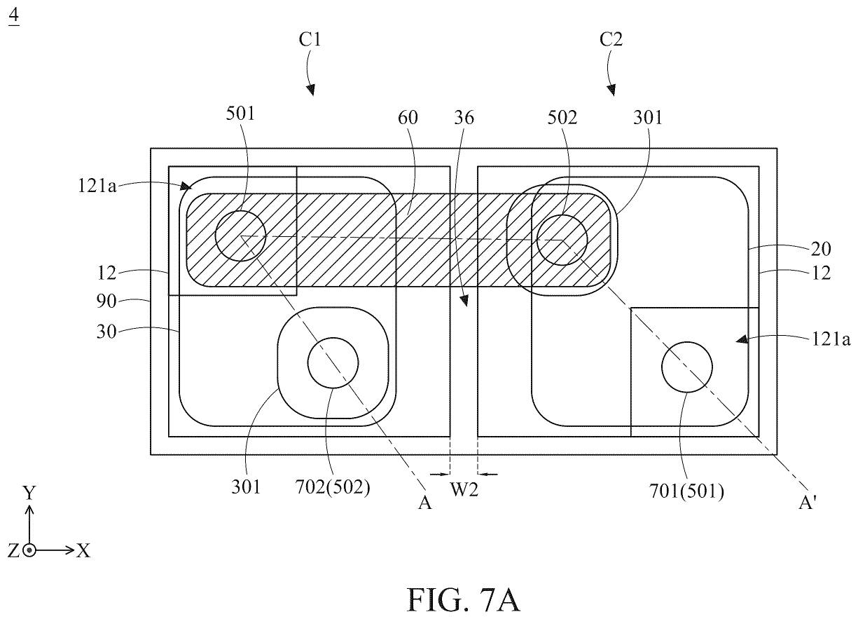

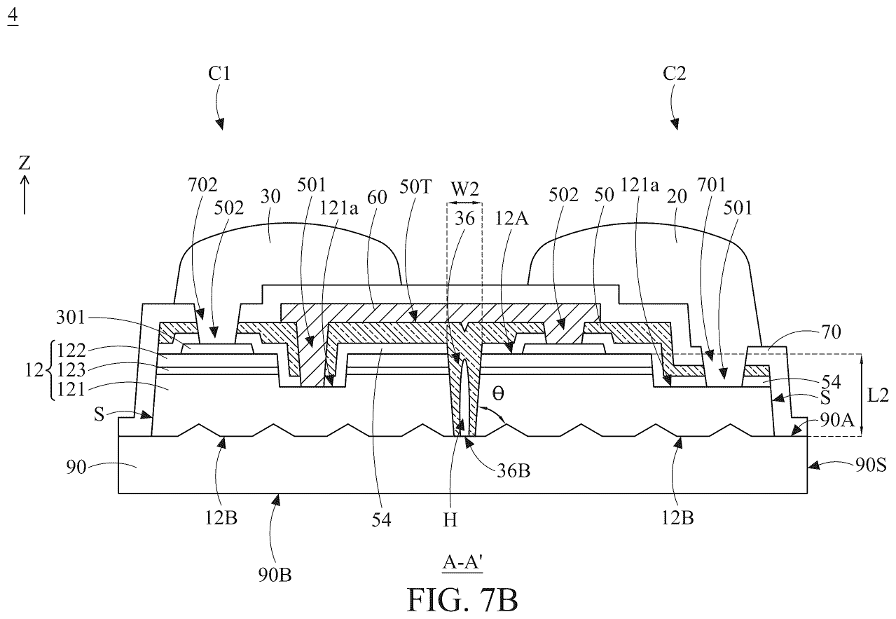

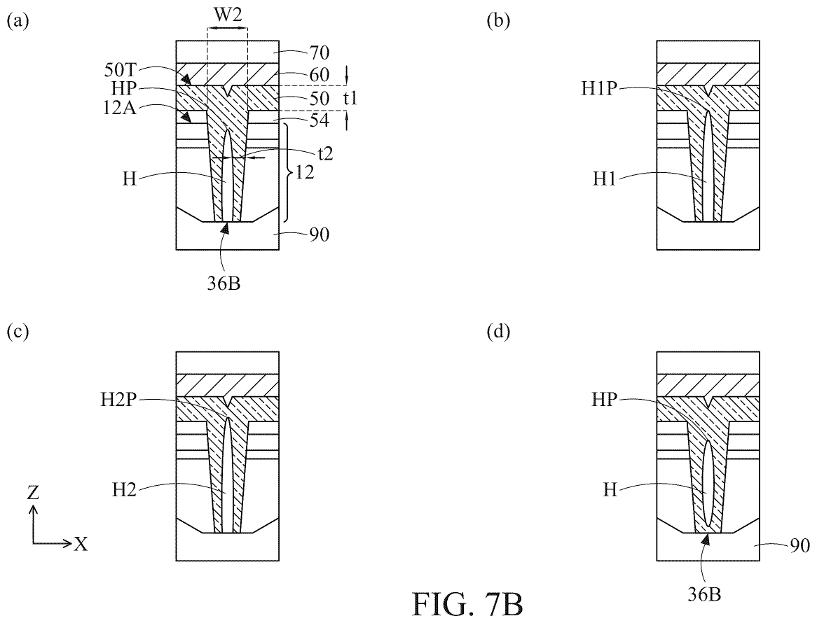

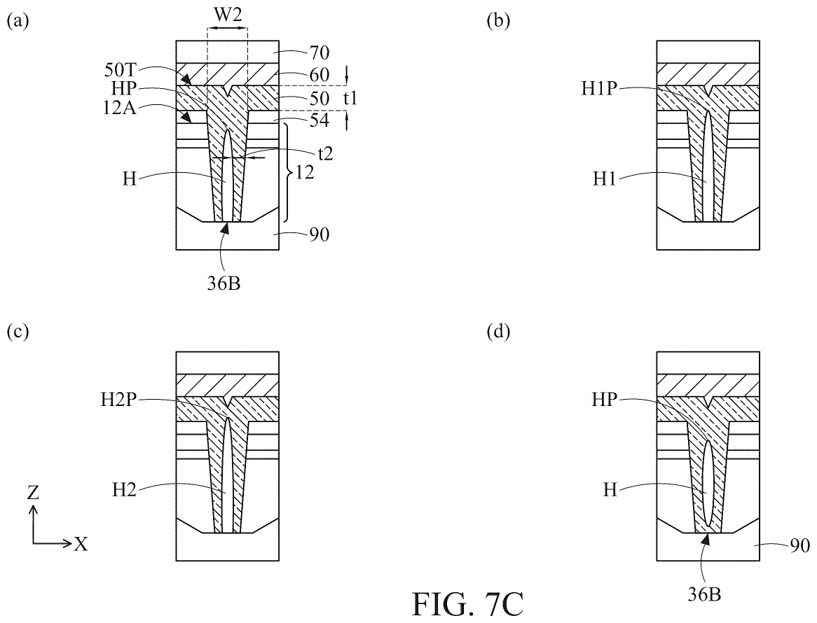

FIG. 7A shows a plan view of a semiconductor device 4 in accordance with another embodiment of the present application. FIG. 7B shows a cross-sectional view taken along line A-A′ of FIG. 7A. The semiconductor device 4 includes a support structure 90, and the semiconductor units C1 and C2 are separately disposed on a top surface 90A of the support structure 90. In this embodiment, the bottom 36B of the trench 36 may be defined by a portion of the top surface 90A of the support structure 90 between the semiconductor units C1 and C2. In one embodiment, L2/W2 is greater than or equal to 1.5. The second insulating structure 70 extends to cover the sidewall S of the semiconductor stack around the periphery of the semiconductor device 4, as well as the top surface 90A of the support structure 90. As shown in FIG. 7A, the upper surface 121a of the first semiconductor layer 121 is disposed at a first corner of the first semiconductor unit C1, and the other upper surface 121a of the first semiconductor layer 121 is exposed at a second corner of the second semiconductor unit C2. The first and second corners are located along a diagonal of the semiconductor device 4. The length of the connection electrode 60 in the X direction is 0.3-0.9 times the length of the longer side of semiconductor device 4. In one embodiment, the length of the connection electrode 60 in the X direction is 0.4-0.8 times the length of the longer side.

The support structure 90 includes one or more insulating materials. In one embodiment, the support structure 90 is transparent to light at the dominant wavelength emitted by the semiconductor stack 12, for example, exhibiting an optical transmittance of at least 80%. The insulating material may include an organic insulating material or an inorganic insulating material. Examples of the organic insulating material include SU-8, benzocyclobutene (BCB), perfluorocyclobutane (PFCB) polymer, epoxy, acrylic resin, cyclic olefin copolymer (COC), polymethyl methacrylate (PMMA), polyethylene terephthalate (PET), polycarbonate (PC), polyetherimide (PEI), or fluorocarbon polymers. Examples of the inorganic material include silicone, glass, silicon oxide (SiO₂), silicon nitride (Si₃N₄), silicon oxynitride (SiON), niobium oxide (Nb₂O₅), hafnium oxide (HfO₂), titanium oxide (TiO₂), magnesium fluoride (MgF₂), or aluminum oxide (Al₂O₃). In one embodiment, the support structure 90 may further include a wavelength-conversion material, such as quantum dots or phosphors, to change the color of the light emitted by the semiconductor stack 12 or to improve the color purity of the emitted light.

The support structure 90 can support the semiconductor units C1 and C2. In one embodiment, the support structure 90 has a thickness of 0.2-3 μm. The top surface 90A of the support structure 90 may optionally include a patterned structure. In FIG. 7B, the bottom surface 90B of the support structure 90, opposite the semiconductor units C1 and C2, serves as the light-extraction surface of the semiconductor device 4 and is substantially planar. In other embodiments, the bottom surface 90B may include a light-extraction structure, such as a patterned structure or a roughened structure. The portion of the top surface 90A of the support structure 90 located around the periphery of the semiconductor device 4 is not covered by the semiconductor stack 12, and a sidewall 90S of the support structure 90 may be substantially flush with the edge of the second insulating structure 70.

FIG. 7C(a) to 7C(d) are enlarged views of the region around trench 36 in FIG. 7B, respectively showing different variations. As shown in FIGS. 7B and 7C, the first insulating structure 50 covers the insulating reflective structure 54, the semiconductor units C1 and C2, and the sidewall of the trench 36. A void H is formed between the semiconductor units C1 and C2. The void H is closed at its top by the first insulating structure 50. The portion of the top surface of the first insulating structure 50 that overlaps the trench bottom 36B is designated as the top surface 50T. The top surface 50T is located farther from the bottom 36B of the trench 36. That is, the top surface 50T is higher than the top surface 12A of the semiconductor stack 12. In other words, the top surface 50T is farther from the bottom surface 12B of the semiconductor stack 12 than the top surface 12A is. In this way, the risk of fracture of the connection electrode 60 and/or the second insulating structure 70 near trench 36 due to topography variations of the first insulating structure 50 (e.g., the high aspect ratio of the trench) can be reduced. In different embodiments, the top surface 50T may be higher than or equal to the top surface of the insulating reflective structure 54. The top surface 50T may be substantially planar, or may exhibit a wrinkle above the void H.

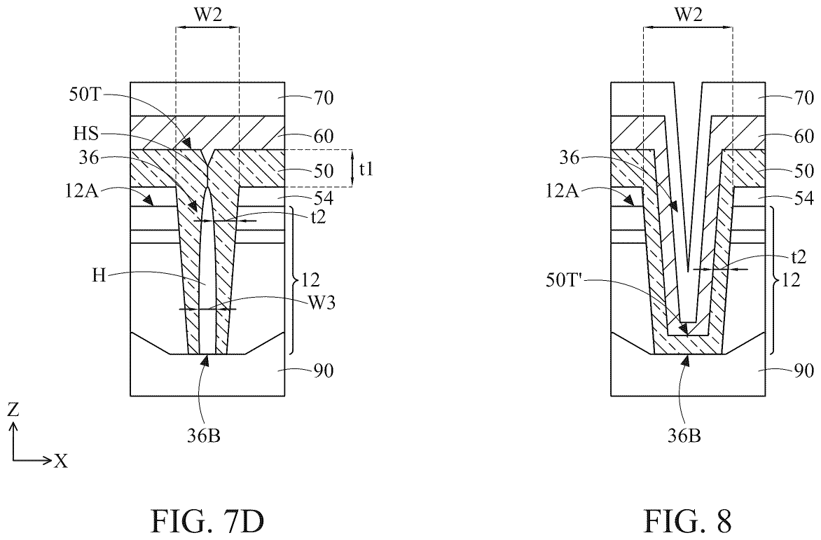

In one embodiment, the first insulating structure 50 is in contact with the bottom 36B of the trench 36. In other embodiments (not shown), the first insulating structure 50 does not cover the sidewall of the trench 36 near the bottom 36B and does not contact the bottom 36B. As shown in FIG. 7C, the thickness t1 of the first insulating structure 50 on planar (horizontal) regions is greater than its thickness t2 on the sidewall of the trench 36. In one embodiment, t1 is greater than or equal to twice t2. By setting the width W2 of the trench within a specified range and adjusting the thickness of the first insulating structure 50, the void H can be formed, and the top surface 50T of the first insulating structure 50 as shown in FIG. 7C can be achieved. For example, if t1 is greater than or substantially equal to W2, the void H can be formed. In a comparative example, as shown in FIG. 8, when t1 and t2 are too thin or W2 is excessively wide, the void H is difficult to form. The first insulating structure 50 may instead be conformally formed on the sidewalls and the bottom 36B of trench 36, such that the top surface 50T′ of the first insulating structure 50 does not exceed the top surface 12A of the semiconductor stack 12.

In one embodiment, the vertical height of the void H along the Z direction can vary depending on t1, W2, and the formation method of the first insulating structure 50. For example, in FIG. 7C (a), the vertical height of the void H along the Z direction does not exceed the depth of the trench 36. That is, the top HP of the void H is lower than the top surface 12A of the semiconductor stack 12. In FIG. 7C (b), the vertical height of the void H1 exceeds the depth of the trench 36 but does not exceed the top surface of the insulating reflective structure 54. In FIG. 7C (c), the vertical height of the void H2 may exceed the top surface of the insulating reflective structure 54. In FIG. 7C (d), the bottom of the void H may be closed by the first insulating structure 50, which extends to the bottom 36B.

In one embodiment, in plan view, the length of the void H (e.g., along the Y direction) may be equal to the length of the trench 36. In other embodiments, the length of the void H may be shorter than the length of the trench 36. In other embodiments, in plan view, the void H may appear as multiple discontinuous segments. In another embodiment, as shown in FIG. 7D, the upper portion of the void H is not completely closed by the first insulating structure 50. The first insulating structure 50 on both sides of the trench 36, above the two semiconductor units, is in close proximity, leaving a slit HS therebetween. In this embodiment, the connection electrode 60 may be formed with a substantially planar top surface over the trench 36, or it may exhibit a slight local wrinkle above the slit HS. In either case, the step coverage of the connection electrode 60 is substantially unaffected by variations in the underlying topography (e.g., those caused by a high-aspect-ratio trench). The top surface 50T of the first insulating structure 50 is located farther from the bottom 36B and higher than the top surface 12A of the semiconductor stack 12, enabling the connection electrode 60 and the second insulating structure 70 to bridge across the trench 36 without being susceptible to fracture due to underlying topography variations (e.g., a high-aspect-ratio trench), thereby achieving the same effect as the structure shown in FIG. 7C.

In one embodiment, different cross-sections of the trench 36 taken at different positions may exhibit the aforementioned different void structures. For example, one cross-section of the trench 36 may show the structure of FIG. 7C, whereas another cross-section of the trench 36 may show the structure of FIG. 7D.

In another embodiment (not shown), the insulating reflective structure 54 may be omitted.

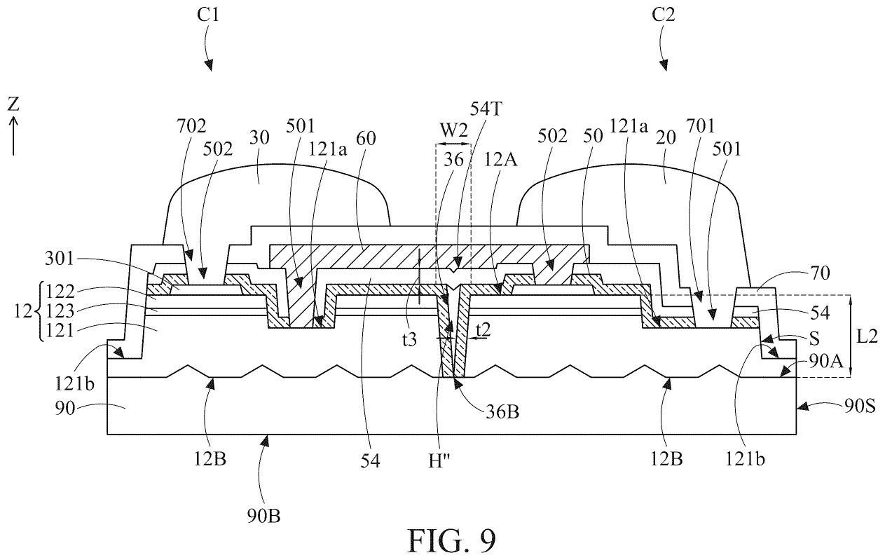

FIG. 9 shows a cross-sectional view of a semiconductor device 5 in accordance with another embodiment of the present application. A plan view of semiconductor device 5 can be found in FIG. 7A. The differences between semiconductor device 5 and semiconductor device 4 are as follows. In FIG. 9, the first insulating structure 50 isa disposed between the insulating reflective structure 54 and the semiconductor stack 12, covering the semiconductor units C1 and C2 and the trench 36. A void H″ is present between the portion of the first insulating structure 50 on the sidewalls of trench 36 and the insulating reflective structure 54, and the portion of the insulating reflective structure 54 corresponding to the void H″ may be suspended. The portion of the top surface of the insulating reflective structure 54 that overlaps the bottom 36B is designated as top surface 54T. The top surface 54T is farther from the bottom 36B and higher than the top surface 12A of the semiconductor stack 12. In this way, the risk of fracture of the connection electrode 60 and/or the second insulating structure 70 near the trench 36 due to underlying topography variations (e.g., a high-aspect-ratio trench) can be reduced. In one embodiment, the thickness t3 of the insulating reflective structure 54 is greater than the thickness of the first insulating structure 50. t2 is less than 0.5 times W2. When t3 is greater than or equal to W2, or when t3 is greater than or equal to (W2−2×t2), the void H″ may be formed. In another embodiment (not shown), the void H as in FIG. 7C or FIG. 7D may first be formed in the first insulating structure 50, after which the insulating reflective structure 54 is formed on the first insulating structure 50.

As shown in FIG. 9, the semiconductor stack 12 around semiconductor device 5 includes a stepped structure. The stepped structure includes a step 121b that is lower than the upper surface 121a of the first semiconductor layer 121. That is, the step 121b is closer to the bottom surface 12B than the upper surface 121a of the first semiconductor layer 121. The top surface 90A of the support structure 90 located around semiconductor device 5 is covered by the semiconductor stack 12, and the second insulating structure 70 further covers the step 121b. In one embodiment, the sidewall 90S of the support structure 90, the edge of the second insulating structure 70, and the edge of the semiconductor stack 12 are substantially flush with one another.

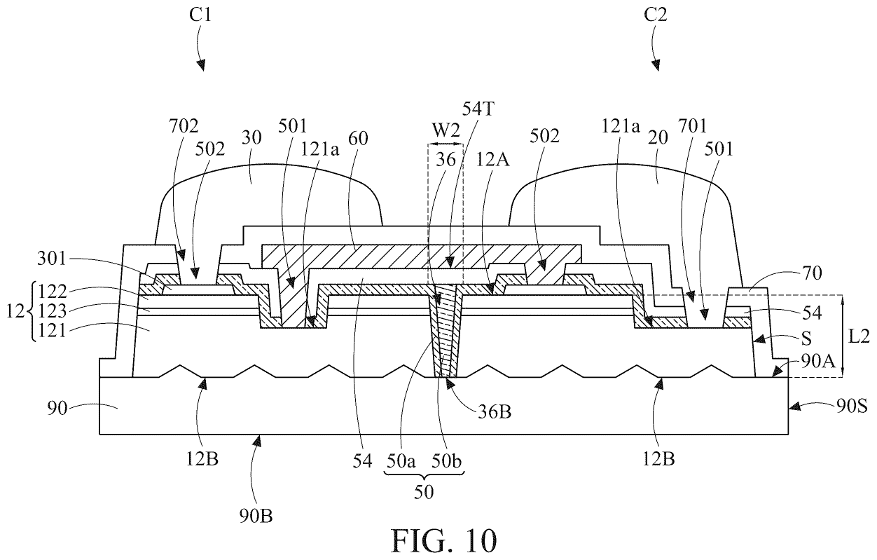

FIG. 10 shows a cross-sectional view of a semiconductor device 6 in accordance with another embodiment of the present application. The differences between semiconductor device 6 and semiconductor device 5 are as follows. Like the semiconductor device 1 shown in FIG. 2, the first insulating structure 50 of semiconductor device 6 includes a first insulating layer 50a that covers the semiconductor units C1 and C2 and the trench 36, and a second insulating layer 50b disposed on the first insulating layer 50a within the trench 36. The second insulating layer 50b may fill the trench 36, such that the overall profile of the first insulating structure 50 above the trench 36 forms a substantially planar top surface. In this way, the risk of fracture of the insulating reflective structure 54 and the connection electrode 60 over the trench 36 can be reduced. In different embodiments, the top surface of the second insulating layer 50b may be substantially flush (slightly higher or slightly lower) with the top surface 12A of the semiconductor stack 12.

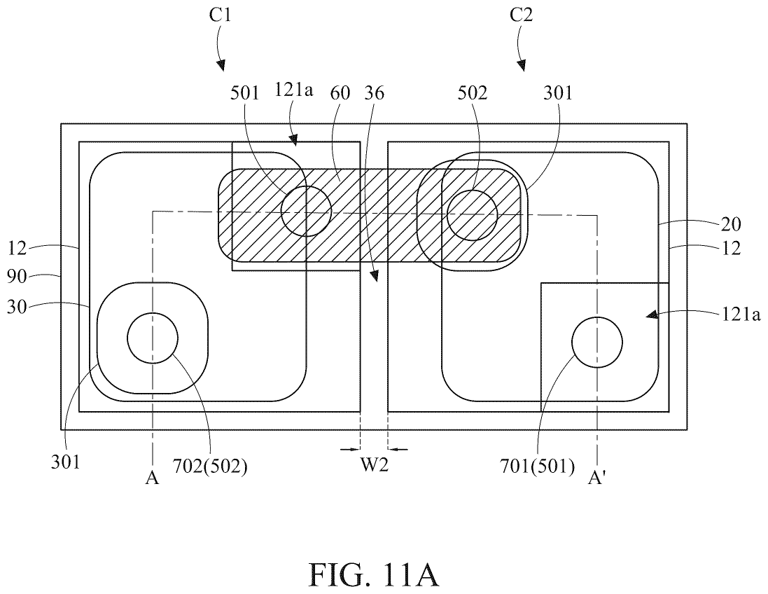

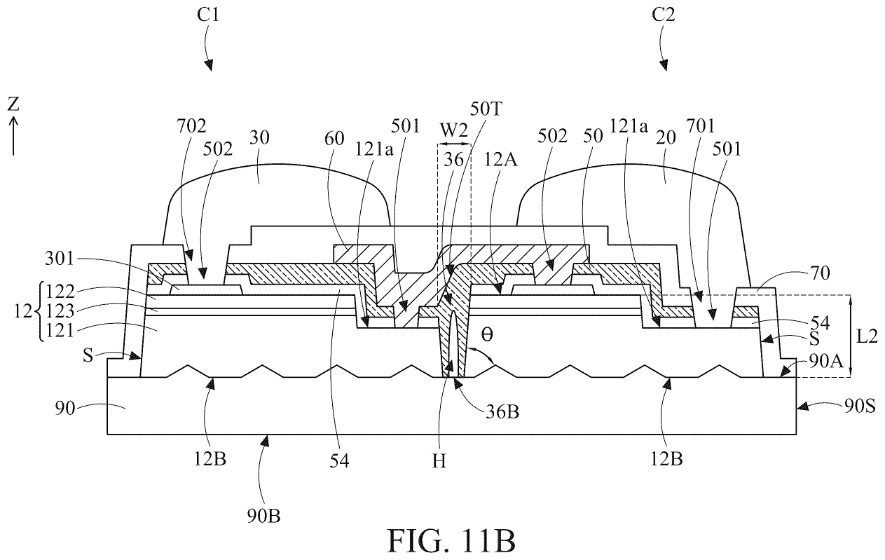

FIG. 11A shows a plan view of a semiconductor device 7 in accordance with another embodiment of the present application. FIG. 11B shows a cross-sectional view taken along line A-A′ in FIG. 11A. The semiconductor device 7 and the semiconductor device 4 have similar structures, except that, as shown in FIGS. 11A and 11B, the upper surface 121a of the first semiconductor layer 121 of the first semiconductor unit C1 is adjacent to the trench 36. Likewise, in the A-A′ cross-section, the void H is formed between the semiconductor units C1 and C2. The configuration of the void H may be as shown in FIG. 7C or FIG. 7D.

Based on the semiconductor devices described in the foregoing embodiments, it will be understood by those of ordinary skill in the art that various modifications, alterations, and combinations may be made without departing from the principles and spirit of the present application. For example, any of the semiconductor devices may include the void(s) H, H″ and/or the support structure 90. The semiconductor device 3 may also include the insulating reflective structure 54. The various combinations of the foregoing embodiments are not described in detail herein.

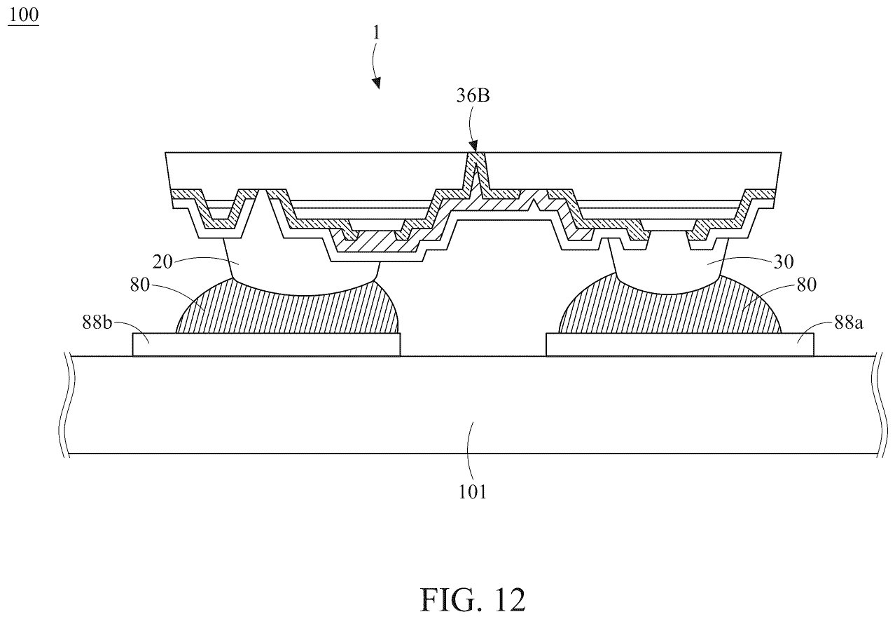

FIG. 12 shows a cross-sectional view of a semiconductor module 100 in accordance with an embodiment of the present application. The semiconductor module 100 includes a circuit board 101 that is provided with circuits (not shown) and circuit bonding pads 88a and 88b. In FIG. 12, semiconductor device 1 is shown by way of example. Any semiconductor device disclosed herein may be mounted in a flip-chip configuration, in which the first electrode pad 20 and the second electrode pad 30 are bonded to circuit bonding pads 88a and 88b, respectively, via a conductive bonding layer 80. In one embodiment, the bonding method includes, but is not limited to, eutectic bonding, solder bonding, or adhesive bonding. The conductive bonding layer 80 may include, for example, a eutectic alloy, a solder, or a conductive adhesive.

In different applications, the semiconductor module 100 may serve as a display module or as a light-emitting module. The semiconductor module 100 includes a plurality of semiconductor devices (not shown) arranged on a circuit board 101. The circuits provided on the circuit board 101 may include active electronic components, such as transistors, and is electrically connected to a plurality of circuit bonding pads 88a and 88b to drive the plurality of semiconductor devices. In one embodiment where the semiconductor module 100 serves as a display module, each semiconductor device may function as a sub-pixel, and a wavelength conversion element is provided on the semiconductor device so that the sub-pixels emit different colors. Adjacent sub-pixels constitute a pixel. The wavelength conversion element may include, for example, quantum dots, phosphors, or color filters. In another embodiment, the semiconductor stacks 12 of the respective semiconductor devices may be formed of different materials, whereby the devices emit light of different colors.

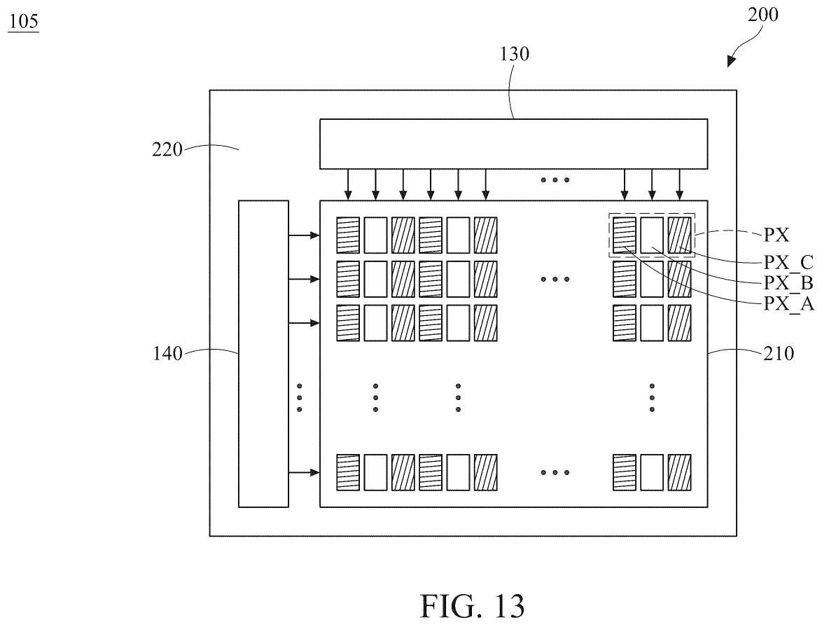

FIG. 13 is a schematic plan view of a display module 105 in accordance with an embodiment of the present application. As shown in FIG. 13, the display module 105 includes a display substrate 200. The display substrate 200 includes a display region 210 and a non-display region 220, and a plurality of pixels PX arranged in the display region 210 of the display substrate 200. Each pixel PX includes a first sub-pixel PX_A, a second sub-pixel PX_B, and a third subpixel PX_C. The non-display region 220 is provided with a data driver 130 and a scan driver 140. The data driver 130 is connected to data lines (not shown) of the respective pixels PX to transmit data signals to the pixels PX. The scan driver 140 is connected to scan lines (not shown) of the respective pixels PX to transmit scan signals to the pixels PX. Any one of the first sub-pixel PX_A, the second sub-pixel PX_B, and the third sub-pixel PX_C may include any of the semiconductor devices of the foregoing embodiments. The sub-pixels emit light of different colors. In one embodiment, the first sub-pixel PX_A, the second sub-pixel PX_B, and the third sub-pixel PX_C are, for example, red, green, and blue sub-pixels, respectively. Semiconductor devices that emit different wavelengths may be selected for the respective sub-pixels so that each sub-pixel emits a different color. By combining the red, green, and blue light emitted by the sub-pixels, the display module 105 can produce full-color images. In other embodiments, a pixel PX may include four or more sub-pixels. In another embodiment, the semiconductor stack 12 in any semiconductor device may include a dual-junction structure, and the semiconductor device may include a plurality of dual-junction structures that are electrically connected in series via the connection electrode 60. In a further embodiment, the second sub-pixel PX_B and/or the third sub-pixel PX_C may include any of the semiconductor devices according to the embodiments disclosed herein, while the first sub-pixel PX_A may include a single semiconductor unit having a dual-junction structure.

It is to be understood that the foregoing embodiments are provided by way of example to illustrate the principles and advantages of the present application and are not intended to limit it. Various modifications, alterations, and combinations may be made by those of ordinary skill in the art without departing from the principles and spirit of the present application. The appended claims are intended to cover all such modifications, variations, and equivalent arrangements, including equivalent changes and modifications to the shapes, structures, and features described herein.

What is claimed is:

1. A semiconductor device comprising:
a plurality of semiconductor units separated from each other by a trench;
an insulating member disposed in the trench and over the plurality of semiconductor units;
a connection electrode disposed on the insulating member, extending laterally across the trench and electrically connecting the plurality of semiconductor units; and
a void disposed in the trench and defined by the insulating member;
wherein the trench comprises a width W, and a vertical distance from a top surface of one of the plurality of semiconductor units to a bottom of the trench is L, with L/W being greater than or equal to 1.5.

2. The semiconductor device of claim 1, wherein the insulating member comprises a first insulating structure and an insulating reflective structure.

3. The semiconductor device of claim 2, wherein the insulating reflective structure is disposed between the first insulating structure and one of the plurality of semiconductor units.

4. The semiconductor device of claim 3, wherein the void is enclosed by the first insulating structure.

5. The semiconductor device of claim 2, wherein the insulating reflective structure is disposed between the first insulating structure and the connection electrode, the first insulating structure contacts a sidewall of the trench, and the void is located between the insulating reflective structure and the first insulating structure.

6. The semiconductor device of claim 5, wherein the insulating reflective structure laterally extends across the void.

7. The semiconductor device of claim 5, wherein the insulating reflective structure comprises a thickness greater than that of the first insulating structure.

8. The semiconductor device of claim 5, wherein the insulating reflective structure comprises a thickness on the top surface; and
the thickness is greater than the width W.

9. The semiconductor device of claim 1, further comprising a second insulating structure covering the connection electrode.

10. The semiconductor device of claim 9, wherein the one of the plurality of semiconductor units comprises:
a step at a periphery of the semiconductor device; and
a first semiconductor layer, an active region and a second semiconductor layer;
wherein the first semiconductor layer comprises an upper surface not covered by the active region and the second semiconductor layer, and
wherein the step is lower than the upper surface.

11. The semiconductor device of claim 10, wherein the second insulating structure further covers the step.

12. The semiconductor device of claim 1, wherein:
the plurality of semiconductor units comprises a first semiconductor unit and a second semiconductor unit;
each of the first semiconductor unit and the second semiconductor unit comprises a first semiconductor layer, an active region, and a second semiconductor layer; and
the connection electrode comprises one end connected to a first upper surface of the first semiconductor layer of the first semiconductor unit,
wherein the first upper surface is spaced apart from the trench.

13. The semiconductor device of claim 12, wherein the first semiconductor layer of the second semiconductor unit comprises a second upper surface;
wherein the semiconductor device further comprises an electrode pad connected to the second upper surface; and
in a plan view, the first upper surface and the second upper surface are located at opposite corners of the semiconductor device along a diagonal thereof.

14. The semiconductor device of claim 1, wherein a top portion of the void is closed by the insulating structure.

15. The semiconductor device of claim 1, wherein in a plan view, each of the plurality of semiconductor units comprises a diagonal length of 5 to 20 μm.

16. The semiconductor device of claim 1, further comprising a high-resistivity semiconductor layer under the plurality of semiconductor units.

17. The semiconductor device of claim 16, wherein the trench extends into the high-resistivity semiconductor layer.

18. The semiconductor device of claim 1, wherein the width W is between 0.2 μm and 3 μm.

19. The semiconductor device of claim 1, wherein the insulating structure comprises openings respectively corresponding to the plurality of semiconductor units, and the connection electrode extends into the openings.

20. A display device, comprising a plurality of pixels, wherein one of the plurality of pixels comprises a plurality of sub-pixels, and one of the plurality of sub-pixels comprises the semiconductor device according to claim 1.
